(19) United States
(12) Patent Application Publication
(10) Pub. No.: US 2010/0276948 A1
(43) Pub. Date: Nov. 4, 2010

(54) LATCHING DEVICE

(75) Inventors: CHENG-TAI SHIH, Tu-Cheng (TW); WEI WU, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/624,418

(22) Filed: Nov. 24, 2009

(30) Foreign Application Priority Data
May 4, 2009 (CN) 200910302093.2

(51) Int. Cl. E05C 1/08; H05K 9/00

(52) U.S. Cl. 292/191; 361/818

(57) ABSTRACT

A latching device includes a first member, a second member defining a locking slot, and a latching member disposed on the first member for locking on the second member. The latching member includes a fixing board extending from the first member, and a deformable resilient tongue connecting with the fixing board away from the first member to form an acute angle with the fixing board.

### BACKGROUND

1. Technical Field

The present disclosure relates to latching devices, and particularly to a latching device having a latching member.

2. Description of Related Art

Screws and/or bolts and nuts are usually used for fastening two components together. However, when one of the two components needs to be disassembled from the other, a screwdriver is needed. Therefore, it is inconvenient for users to disassemble the components.

Therefore, it is desirable to provide a latching device with a latching member which can overcome the above-mentioned problems.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric view of the latching device according to an exemplary embodiment.

FIG. 2 is an exploded isometric view of a latching device of FIG. 1.

FIG. 3 is a partial enlarged view of a circled portion III of FIG. 2.

### DETAILED DESCRIPTION

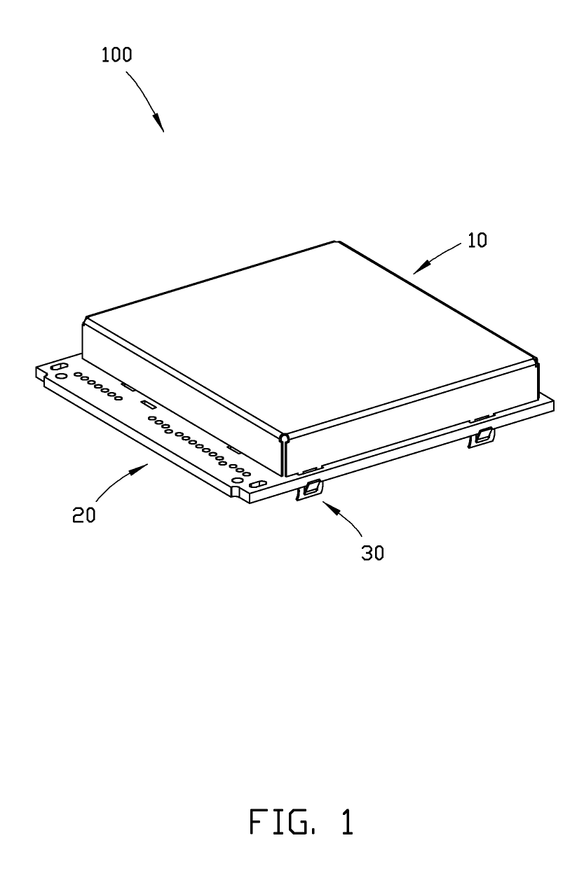

Referring to FIG. 1, a latching device 100 according to an exemplary embodiment includes a first member 10, a second member 20, and a latching member 30 disposed on the first member 10. The latching member 30 is locked on the second member 20 by the latching member 30.

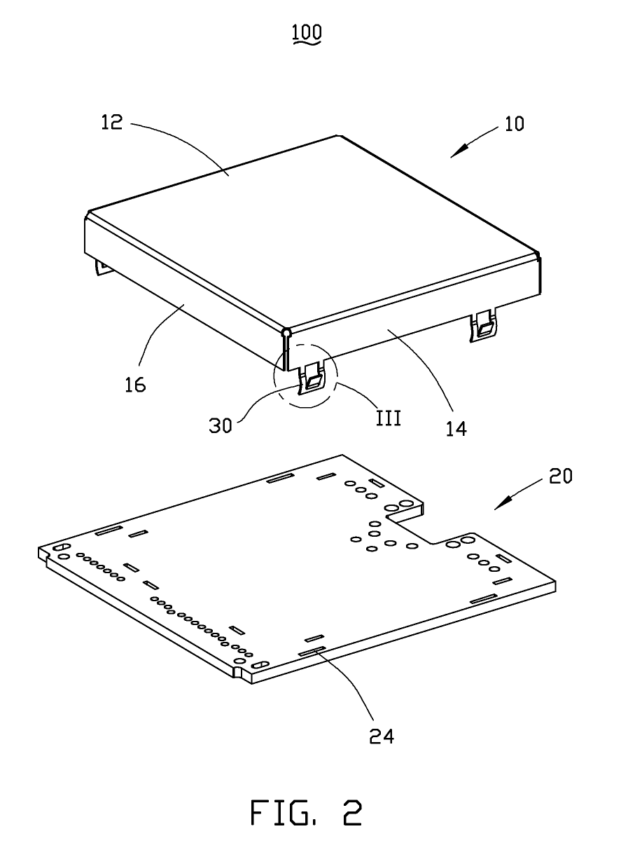

Further referring to FIG. 2, the first member 10 includes a substantially rectangular base board 12, two first sidewalls 14, and two second sidewalls 16. The two first sidewalls 14 and the two second sidewalls 16 perpendicularly extend from the four edges of the base board 12 correspondingly. The two first sidewalls 14 are parallel with each other and the two second sidewalls 16 are parallel with each other too. Each of the two first sidewalls 14 is perpendicular to each of the two second sidewalls 16.

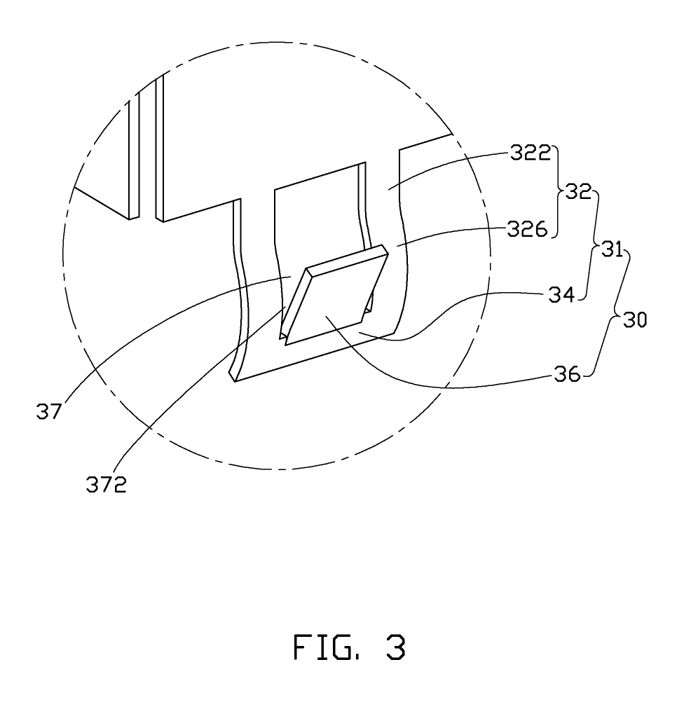

The latching member 30 is disposed on one of the first sidewalls 14 away from the base board 12. Further referring to FIG. 3, the latching member 30 includes a fixing board 31 and a resilient tongue 36. The fixing board 31 includes two supporting parts 32, a connecting part 34. The two supporting parts 32, a connecting part 34, and the first member 10 cooperatively define an opening 37.

The two supporting parts 32 are parallel arms connected with the one of the first sidewalls 14 away from the base board 12. Each of the two supporting parts 32 includes a cantilever 322 and a bent portion 326. The cantilever 322 directly connects with the one of the first sidewalls 14 away from the base board 12. The bent portion 326 connects with the cantilever 322 away from the one of the first sidewalls 14. A bending direction of the bent portion 326 is opposite to the other one of the first sidewalls 14.

The connecting part 34 is an elongated portion for connecting two ends of the two bent portions 326 away from the cantilevers 322. Therefore, the two supporting parts 32 and the connecting part 34 substantially form a U-shaped structure.

The resilient tongue 36 is flatly connected with the connecting part 34 adjacent to the one of the first sidewalls 14, and slantly extend opposite to the other one of the first sidewalls 14. Therefore, an acute angle is formed between the resilient tongue 36 and the fixing board 32. An extending direction of the resilient tongue 36 is the same as the bending direction of the bent portion 326. A length of the resilient tongue 36 is substantially equal to that of the bent portion 326, and a width of the resilient tongue 36 is smaller than a distance of the two bent portions 326.

In the embodiment, the number of the latching members 30 is four, two of the latching members 30 are disposed at one of the two sidewalls 14, the other two of the latching members 30 are disposed at the other one of the two sidewalls 14. In other embodiments, the number of the latching members 30 may be one, two, three, five, and more.

The second member 20 defines four locking slots 24 (see FIG. 1) corresponding to the four latching members 30.

When the first member 10 needs to be fixed on the second member 20, the first member 10 is positioned adjacent the second member 20 such that the latching members 30 are aligned with the locking slots 24 correspondingly. The first member 10 is then pressed against the second member 20, such that the connecting part 34 of the latching member 30 resiliently bends into the locking slot 24, and the resilient tongue 36 resiliently deforms parallel between the two bent portions 326. As a result, the resilient tongue 36 and the bent portions 326 are insertable and passed into the locking slot 24. After that, the resilient tongue 36 returns to normal to latch onto the second member 20, hence, the second member 20 is clipped between the first sidewall 14 and the latching member 30. The first member 10 is fastened on the second member 20.

When the first member 10 needs to be released from the second member 20, a pushing force is applied on the resilient tongue 36, the resilient tongue 36 deforms to be received between the two bent portions 326. Therefore, the latching member 30 can be freed from the locking slot 24 and the first member 10 is released from the second member 20. Therefore, there is no need for a screwdriver to disassemble the latching member 30 from the second member 20, and it is convenient to disassemble the latching device 100.

In the embodiment, the first member 10 is made of shielding material, the second member 20 comprises a printed circuit board, the first member 10 is locked to the second member 20 by the latching member 30 for electromagnetic interference (EMI) protection.

It is to be understood, however, that even though numerous characteristics and advantages of the present disclosure have been set forth in the foregoing description, together with details of the structure and function of the present disclosure, the present disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A latching device, comprising:
a first member;
a second member defining a locking slot; and
a latching member disposed on the first member for passing through the locking slot to lock on the second member; the latching member comprising:
a fixing board extending from the first member;
a deformable resilient tongue connecting with the fixing board and extending away from the first member to form an acute angle with the fixing board.

2. The latching device of claim 1, wherein the fixing board defines an opening, the resilient tongue deforms to be received in the opening.

3. The latching device of claim 1, wherein the fixing board comprises two supporting parts and a connecting part connecting the two supporting parts away from the first member, the resilient tongue extends from the connecting part.

4. The latching device of claim 3, wherein the resilient tongue connects with the connecting part adjacent to the first member, and is capable of deforming to be receive between the two supporting parts.

5. The latching device of claim 3, wherein the two supporting parts extend parallel with each other.

6. The latching device of claim 3, wherein each of the two supporting parts comprises a cantilever connecting with the first member and a bent portion connecting the cantilever and the connecting part.

7. The latching device of claim 6, wherein the first member comprises a base board and two parallel sidewalls perpendicularly extending from the base board, the fixing board is disposed on one of the two parallel sidewalls away from the base board, a bending direction of the bent portion is opposite to the other one of the two parallel sidewalls.

8. The latching device of claim 6, wherein a length of the resilient tongue is substantially equal to that of the bent portion.

9. The latching device of claim 6, wherein a width of the resilient tongue is smaller than a distance defined between the two bent portions.

10. The latching device of claim 1, wherein the resilient tongue is flat.

11. The latching device of claim 1, wherein the first member is made of shielding material, the second member comprises a printed circuit board, the first member is locked to the second member by the latching member for EMI protection.
